(19) United States
(12) Patent Application Publication
(10) Pub. No.: US 2022/0139755 A1
(43) Pub. Date: May 5, 2022

(54) SEMICONDUCTOR MANUFACTURING APPARATUS AND CHIP HANDLING METHOD

(71) Applicant: Samsung Electronics Co., Ltd., Suwon-si (KR)

(72) Inventors: Naoyuki TAKADA, Yokohama-shi (JP); Masato KAJINAMI, Yokohama-shi (JP); Tatsuya ISHIMOTO, Yokohama-shi (JP)

(73) Assignee: Samsung Electronics Co., Ltd., Suwon-si (KR)

(21) Appl. No.: 17/375,263

(22) Filed: Jul. 14, 2021

(30) Foreign Application Priority Data
Oct. 30, 2020 (JP) 2020-182079
Jan. 15, 2021 (KR) 10-2021-0006048

(51) Int. Cl. H01L 21/683

(52) U.S. Cl. CPC H01L 21/6838

(57) ABSTRACT

A semiconductor manufacturing apparatus comprises an adsorption unit defining a plurality of pressing holes in the adsorption unit, the plurality of pressing holes configured to eject gas, and defining a plurality of suction holes in the adsorption unit, the plurality of suction holes configured to suction the gas and to handle a semiconductor chip through the gas. At least one of the suction holes is adjacent to at least one of an apex of the adsorption unit or an edge of the adsorption unit.

### CROSS-REFERENCE TO RELATED APPLICATION(S)

This application claims the benefit of Korean Patent Application No. 10-2021-0006048, filed on Jan. 15, 2021, in the Korean Intellectual Property Office, and Japanese Patent Application No. 2020-182079 filed on Oct. 30, 2020 in the Japanese Patent Office, the disclosures of each of which are incorporated herein by reference in their entirety.

### BACKGROUND

Some example embodiments relate to a semiconductor manufacturing apparatus and/or a chip handling method.

In a semiconductor mounting process according to related art, a bump has been included by inserting a sealing material between a chip and a wafer. However, as high-density mounting is being used, a direct bonding process using no bump is being pursued.

In the above techniques, a functional group is exposed by surface activation using plasma and/or the like, and the functional groups are bonded to each other. Accordingly, bonding is stronger and/or closer, and does require a height of the bump, so that higher density may be implemented. However, since an activated surface has a significantly precise flatness and has a high degree of cleanliness, there is ongoing research into various methods. For example, a plasma treatment is performed by division with equipment such as those provided by Toray Engineering Co., Ltd, and a batch treatment with wafer-on-wafer may then be performed.

However, since such methods are significantly different from an existing bonding method, a large amount of time for production is used.

A method of adsorbing activated chips in a non-contact manner has been studied to implement a flip-chip bonding method according to the related art, in which a diced chip is picked up and then transmitted a bonding head.

A chip may be held in a non-contact manner, but it may be difficult to maintain an orientation of the chip in the horizontal direction. Therefore, a method of placing a component serving as a stopper even when a pin or a nail is raised and moved in a horizontal direction has generally been used.

As described above, a high degree of cleanliness is used, so that when a pin and/or a nail are used, the pin and/or the nail are brought into contact with a diced end portion of a chip to cause generation of particles.

### SUMMARY

Some example embodiments provide chip handling to satisfy either or both maintenance of a location of a chip in a horizontal direction and high degree of cleanliness.

A semiconductor manufacturing apparatus according to some example embodiments includes an adsorption unit defining a plurality of pressing holes in the adsorption unit, the plurality of pressing holes configured to eject gas, and defining a plurality of suction holes in the adsorption unit, the plurality of suction holes configured to suction the gas and to handle a semiconductor chip through the gas. At least one of the suction holes is adjacent to at least one of an apex of the adsorption unit or an edge of the adsorption unit.

The semiconductor manufacturing apparatus according to some example embodiments may satisfy both maintenance of a location of a chip in a horizontal direction and a high degree of cleanliness.

The semiconductor manufacturing apparatus according to some example embodiments may include a pressing unit connected to the pressing holes, the pressing unit configured to deliver the gas and a suction unit connected to the suction holes, the suction unit configured to suction the gas.

In the semiconductor manufacturing apparatus according to some example embodiments, a sum of cross-sectional areas of the plurality of suction holes is greater than a sum of cross-sectional areas of the plurality of pressing holes.

In the semiconductor manufacturing apparatus according to some example embodiments, the adsorption unit includes a first adsorption region and a second adsorption region surrounding the first adsorption region, and the plurality of suction holes include a first suction hole in the first adsorption region and adjacent to an edge of the first adsorption region, and a second suction hole in the second adsorption region and adjacent to an edge of the second adsorption region.

In the semiconductor manufacturing apparatus according to some example embodiments, the adsorption unit has a shape of a polygon when viewed in plan view.

In the semiconductor manufacturing apparatus according to some example embodiments, the adsorption unit has a shape of a triangle when viewed in plan view.

In the semiconductor manufacturing apparatus according to some example embodiments, the adsorption unit has a shape of a triangle when viewed in plan view.

In the semiconductor manufacturing apparatus according to some example embodiments, the adsorption unit has a shape of a pentagon when viewed in plan view.

In the semiconductor manufacturing apparatus according to some example embodiments, at least one of the suction holes is adjacent to an apex of the adsorption unit, and at least one other of the suction holes is adjacent to a an edge of the adsorption unit.

In the semiconductor manufacturing apparatus according to some example embodiments, at least one of the suction holes in a center of the adsorption unit.

In the semiconductor manufacturing apparatus according to some example embodiments, the adsorption unit corresponds to a table.

In the semiconductor manufacturing apparatus according to some example embodiments, there may be a pressing unit tube connecting the pressing unit to at least one of the pressing holes.

In the semiconductor manufacturing apparatus according to some example embodiments, there may be a suction unit tube connecting the suction unit to at least one of the suction holes.

In the semiconductor manufacturing apparatus according to some example embodiments, the apex of the adsorption unit corresponds to a sharp corner of the adsorption unit.

In the semiconductor manufacturing apparatus according to some example embodiments, the apex of the adsorption unit corresponds to a beveled corner of the adsorption unit.

In the semiconductor manufacturing apparatus according to some example embodiments, the apex of the adsorption unit corresponds to a chamfered corner of the adsorption unit.

In the semiconductor manufacturing apparatus according to some example embodiments, at least one of the pressing holes has a size of 50 μm or less.

In the semiconductor manufacturing apparatus according to some example embodiments, at least one of the suction holes has a size of between 0.4 mm and 0.6 mm.

A semiconductor manufacturing apparatus according to some example embodiments includes an adsorption table defining a plurality of pressing holes within the adsorption table, the plurality of pressing holes configured to eject gas, and defining a plurality of suction holes in the adsorption table, the plurality of suction holes configured to suction the gas and to handle a semiconductor chip through the gas. At least one of the suction holes is adjacent to at least one of a corner of the adsorption table or an edge of the adsorption table.

In the semiconductor manufacturing apparatus according to some example embodiments, at least one of (A) the plurality of suction holes are symmetrically arranged in the adsorption table, or (B) the plurality of pressing holes are symmetrically arranged in the adsorption table.

A semiconductor manufacturing apparatus according to some example embodiments includes using an adsorption unit surrounding a plurality of pressing holes configured to eject gas and a plurality of suction holes configured to suction the gas and to handle a semiconductor chip through the gas, the adsorption unit configured to suction the gas from the suction holes at the same time as the gas is ejected from the pressing holes. At least one of the suction holes is in a location adjacent to at least one of an apex of the adsorption unit or an edge of the adsorption unit.

In the semiconductor manufacturing apparatus according to some example embodiments, with only a shape of a hole, a suction pressure may be always be high and gas may be continuously discharged such that a chip may float. Therefore, external particles may be reduced or prevented from entering the apparatus.

In the semiconductor manufacturing apparatus according to some example embodiments.

According to the semiconductor manufacturing apparatus of some example embodiments, chip handling may be performed to correspond to a plurality of chip sizes.

A chip handling method according to some example embodiments may include.

The chip handling method according to some example embodiments may satisfy maintenance of a location of a chip in a horizontal direction and/or a high degree of cleanliness.

### BRIEF DESCRIPTION OF DRAWINGS

The above and other aspects, features, and advantages of some example embodiments will be more clearly understood from the following detailed description, taken in conjunction with the accompanying drawings.

FIG. 1 is a view illustrating a schematic configuration of a semiconductor device according to some example embodiments.

FIG. 2 is a view illustrating an example in which the semiconductor device according to some example embodiments adsorbs a chip.

FIG. 3 is a view illustrating an example in which the semiconductor device according to some example embodiments adsorbs a chip.

FIG. 4 is a view illustrating an example of an adsorption unit of a semiconductor manufacturing apparatus according to some example embodiments.

FIG. 5 is a view illustrating an example of an adsorption unit of a semiconductor manufacturing apparatus according to some example embodiments.

FIG. 6 is a view illustrating an example of an adsorption unit of a semiconductor manufacturing apparatus according to some example embodiments.

FIG. 7 is a view illustrating an example of an adsorption unit of a semiconductor manufacturing apparatus according to some example embodiments.

FIG. 8 is a view illustrating an example of an adsorption unit of a semiconductor manufacturing apparatus according to some example embodiments.

FIG. 9 is a view illustrating a schematic configuration of a semiconductor device according to some example embodiments.

FIG. 10 is a view illustrating an example of an adsorption embodiment of a semiconductor manufacturing apparatus according to other some example embodiments.

### DETAILED DESCRIPTION OF SOME EXAMPLE EMBODIMENTS

Hereinafter, some example embodiments will be described with reference to the accompanying drawings.

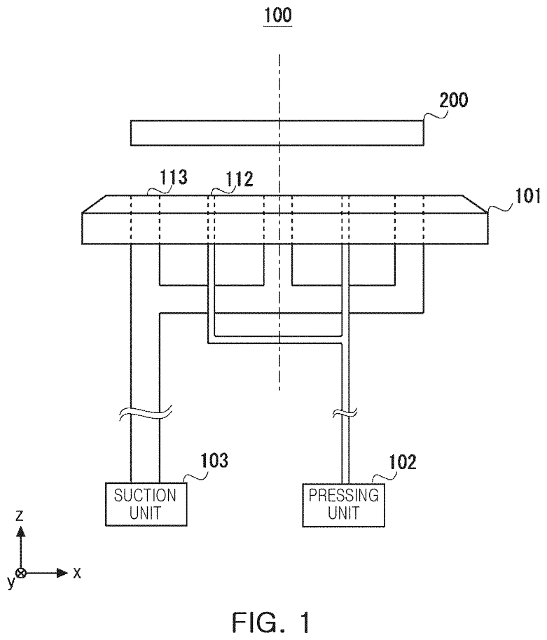

FIG. 1 is a view illustrating a schematic configuration of a semiconductor device according to some example embodiments. In FIG. 1, a semiconductor manufacturing apparatus may include an adsorption unit 101, a pressing unit 102, and a suction unit 103.

The adsorption unit 101 may have at least one plane for handling a chip 200. The adsorption unit 101 may correspond to a shape of the chip 200 to be handled. The adsorption unit 101 may include a plurality of pressing holes 112 and a plurality of suction holes 113 formed in the plane. The adsorption unit 101 may be or correspond to a table or a platen or a tool. The adsorption unit may be composed of or include a metal and/or a ceramic and/or a polymer; however, example embodiments are not limited thereto.

The pressing hole 112 may be or correspond to a hole for ejecting gas toward a surface on which the adsorption unit 101 handles the chip 200. In some example embodiments, the pressing hole 112 may be disposed in the vicinity of the suction hole 113. The pressing hole 112 may have a size, e.g. a diameter, of 50 μm or less. The pressing hole 112 may be circular in shape; however, example embodiments are not limited thereto, and the pressing hole 112 may be oval shaped, and/or elliptical shaped, and/or square shaped or rectangular shaped, and/or have a polygon shape.

The suction hole 113 may be a hole for suctioning gas from a surface on which the adsorption unit 101 handles the chip 200. The suction hole 113 may be disposed in a location adjacent to an edge of a surface of the adsorption unit 101. For example, at least one of the suction holes 113 may be disposed on an apex of (e.g. a corner of) the surface of the adsorption unit 101. For example, the suction hole 113 may be disposed in a location which is not outside of the size range of the chip 200 that is to be adsorbed in a non-contact manner. The suction hole 113 may be provided at a position other than those described above. For example, at least one of the suction hole 113 may be arranged in a center of the surface of the adsorption unit 101. The suction hole 113 may have a size of (e.g. a diameter of), in detail, 0.5 mm, for example between 0.4 mm and 0.6 mm. The suction hole 113 may be circular in shape; however, example embodiments are not limited thereto, and the suction hole 113 may be oval shaped, and/or elliptical shaped, and/or square shaped or rectangular shaped, and/or have a polygon shape, and may have the same shape or different shapes from that of the pressing hole 112. A number of the suction holes 113 may be the same as, or greater than, or less than a number of the pressing holes 112. A detailed location of the suction hole 113 will be described later. In some example embodiments, the sum of the cross-sectional areas of the plurality of suction holes 113 may be greater than the sum of the cross-sectional areas of the plurality of pressing holes 112.

The pressing unit 102 may be connected to the pressing hole 112 to deliver gas. The pressing unit 102 may include, for example, a cylinder filled with an inert gas such as nitrogen and/or helium, a regulator, a flow control valve such as flow control valve controlled by a mass flow controller, and a positive injection pump (PIP). The pressing unit 102 may include, for example, a pump such as a positive injection pump (PIP). Set pressure provided by the pressing unit 102 may be within the range of, for example, between 0.2 MPa to 0.6 MPa. The pressing unit 102 may include a blower such as a blowing motor; however, example embodiments are not limited thereto. There may be a connection, such as a tube, between the pressing unit 102 and each of the corresponding pressing holes 112. Furthermore there may be more than one pressing units connected to pressing holes 112. The tubes may be hollow, and may be plastic; however, example embodiments are not limited thereto.

The suction unit 103 is connected to the suction hole 113 to such gas. For example, the suction unit 103 may also include a pump and a PIP. Suction pressure of the suction unit 103 may be within the range of, for example, 83 kPa to 70 kPa. The suction unit 103 may include a vacuum; however, example embodiments are not limited thereto. There may be a connection, such as a tube, between the suction unit 103 and each of the corresponding suction holes 113. Furthermore there may be more than one pressing units connected to suction holes 113. The tubes may be hollow, and may be plastic; however, example embodiments are not limited thereto.

According to the above-configured semiconductor manufacturing apparatus 100, the chip 200 may float at a distance, e.g. at a certain distance from the adsorption unit 101 due to a suction force for vacuum adsorption from a hole of the suction hole 113 disposed on the adsorption unit 101, and also pressing from pressing holes 112 uniformly disposed around a hole in which the vacuum adsorption is performed. For example, the chip 200 may float similarly as an air hockey puck floats. The adsorption unit 101 may correspond to an air hockey table; however, example embodiments are not limited thereto.

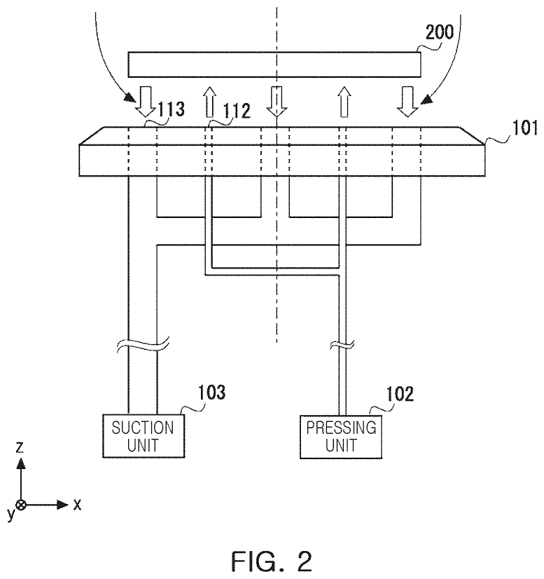

Hereinafter, a description will be provided as to the principle in which a location of the chip 200 is maintained while adsorbing the chip 200 to the adsorption unit 101 in a non-contact manner. FIG. 2 is a view illustrating an example in which the semiconductor device according to some example embodiments adsorbs a chip.

As illustrated in FIG. 2, when a chip 200 is disposed along a center of an adsorption unit 101, gas ejected from a pressing hole 112 may be suctioned into the suction hole 113. In addition, surrounding gas may be suctioned into the suction hole 113 on an edge of a side surface of the chip 200. Since flows of the suctioned gases may be balanced on edges, the chip 200 may be adsorbed to the suction section 101 to reduce or prevent misalignment of the chip 200.

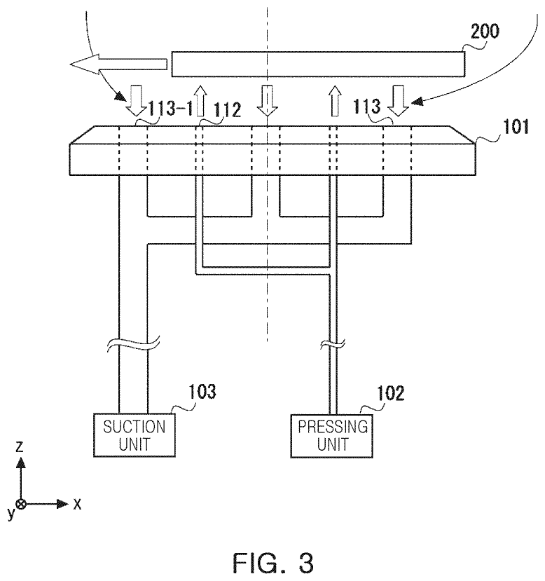

Hereinafter, a description will be provided as to some example embodiments in which the chip 200 is misaligned with the adsorption unit 101. FIG. 3 is a view illustrating an example in which the semiconductor device according to some example embodiments adsorbs a chip.

As illustrated in FIG. 3, when a chip 200 is misaligned with the adsorption unit 101, e.g. when a center of the chip 200 is not aligned with a center of the adsorption unit 101, a portion of the suction hole 113 may not be covered with the chip 200 and may be exposed from the chip 200. As illustrated in FIG. 3, when a suction hole 113-1 is exposed, gas in the vicinity of the suction hole 113-1 may be suctioned. As a result, in the vicinity of the suction hole 113-1, gas may flow at high speed and a pressure may be lower than a surrounding pressure. Accordingly, the chip 200 may move in a direction in which a pressure is decreased. For example, the chip 200 may move in a direction in which an upper surface of the exposed suction hole 113-1 is covered.

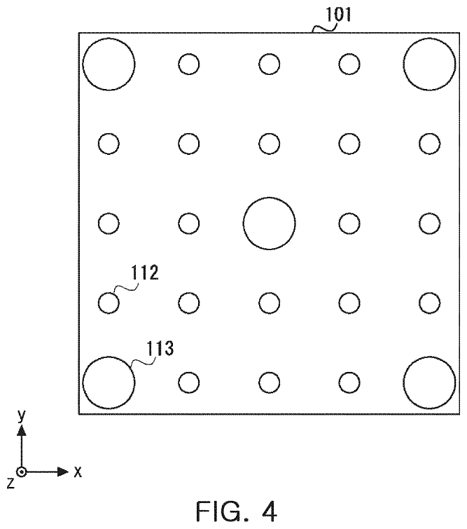

A location of the chip 200 may be maintained based on the above-described principle. For example, a center of the chip 200 may be aligned with a center of the adsorption unit 101. Hereinafter, an example of a shape of the adsorption unit 101 will be described. FIG. 4 is a view illustrating an example of an adsorption unit of a semiconductor manufacturing apparatus according to some example embodiments when viewed in plan view. In FIG. 4, a surface on which an adsorption unit 101 handles a chip 200 is illustrated as having a rectangular shape; however, example embodiments are not limited thereto. The surface of the adsorption unit may be rectangular, e.g. may be square, or may be polygonal other than rectangular, and/or may have a chamfered corner and/or a beveled corner. The apex of the adsorption unit 101 may be a corner of a polygon, and may be a sharp corner, and/or a chamfered corner, and/or a beveled corner. A distance between a corner of the adsorption unit 101 and a center of one of the suction holes 113 may be between 0.1 mm and 1 mm; however, example embodiments are not limited thereto. As illustrated in FIG. 4, at least one suction hole 113 may be disposed in a location adjacent to an edge of a surface of the adsorption unit 101, in particular, on an apex of (e.g. a corner of) the surface of the adsorption unit 101. Alternatively or additionally, at least one suction hole 113 may be provided in a center of a rectangle, other than an apex. A plurality of pressing holes 112 may be prepared in a certain location of the adsorption unit 101. The suction holes 113 may be arranged symmetrically within the adsorption unit 101; alternatively or additionally the pressing holes 112 may be arranged symmetrically within the adsorption unit 101; however, example embodiments are not limited thereto.

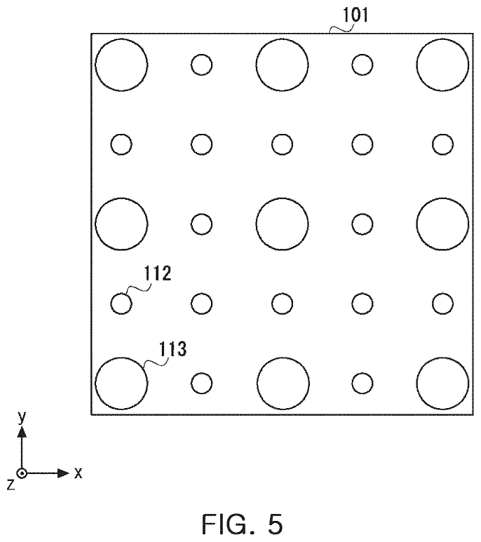

The suction hole 113 may be disposed in a position adjacent to an edge of the surface of the adsorption unit 101, for example, in a region other than or in addition to the apex of the surface of the suction unit 101. FIG. 5 is a view illustrating an example of an adsorption unit of a semiconductor manufacturing apparatus according to some example embodiments. In FIG. 5, a suction hole 113 is illustrated as being provided in a location of an edge other than (e.g. in addition to) an apex in addition to the location illustrated in FIG. 4.

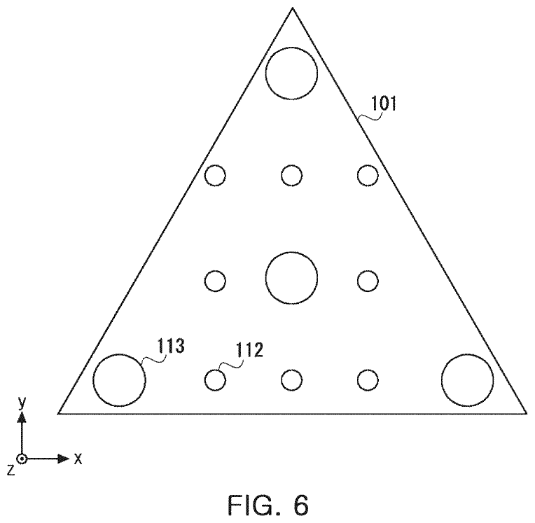

The suction unit 101 may have a triangular shape. For example, FIG. 6 is a view illustrating an example of an adsorption unit of a semiconductor manufacturing apparatus according to some example embodiments. In FIG. 6, a surface on which an adsorption unit 101 handles a chip 200 is illustrated as having a triangular shape. The triangular shape may be that of an equilateral triangle; however, example embodiments are not limited thereto.

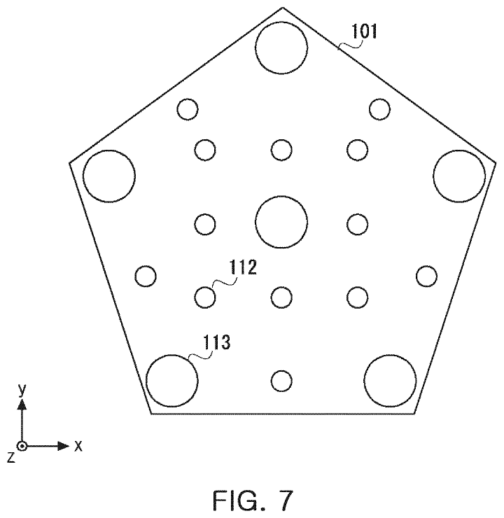

Alternatively, the suction unit 101 may have a pentagonal shape. FIG. 7 is a view illustrating an example of an adsorption unit of a semiconductor manufacturing apparatus according to some example embodiments. In FIG. 7, a surface on which an adsorption unit 101 handles a chip 200, is illustrated as having a pentagonal shape. The pentagonal shape may be that of a regular pentagon; however, example embodiments are not limited thereto.

For ease of description, in FIGS. 4 to 7, regular polygons are illustrated as examples, but sides may have different lengths. Alternatively or additionally, asymmetrical polygons may be applied as examples.

As described above, chips 200 having various shapes may be applied to corresponding adsorption units 101, respectively.

Hereinafter, an example of a handling operation using a semiconductor manufacturing apparatus 100 will be described.

When a chip is picked up from a diced wafer to a flip-chip head including an adsorption unit 101, the flip-chip head may be brought close to a wafer, and a portion of the chip may be lifted from a lower side of the wafer by an ejector pin, and/or the like. When a pressing unit 102 and an adsorption unit 103 operate together, the chip may be simultaneously pressed and suctioned by the flip-chip head, and may be adsorbed in the state of being spaced apart from the adsorption unit 101 by, for example, about 5 μm to about 200 μm.

After the chip is adsorbed, the chip may be moved to an adsorption location of a bonding head while inverting a head to perform a flip operation.

When the chip is adsorbed on (bonded on) the bonding head, pressing and suction on the flip chip head side may be stopped.

As described above, the semiconductor manufacturing apparatus according to some example embodiments may automatically inhibit or reduce the likelihood of misalignment in a horizontal direction while performing non-contact adsorption. Alternatively or additionally, the semiconductor manufacturing apparatus according to some example embodiments may automatically correct misalignment in a rotational direction while performing non-contact adsorption. Alternatively or additionally, in the semiconductor manufacturing apparatus according to some example embodiments, a shape of a location-maintained hole may be changed by changing a layout of a suction hole and a pressing hole. In addition, the semiconductor manufacturing apparatus according to some example embodiments may reduce or prevent external particles from entering the apparatus because a suction press is always high and compressed air is continuously discharged to allow a chip to float.

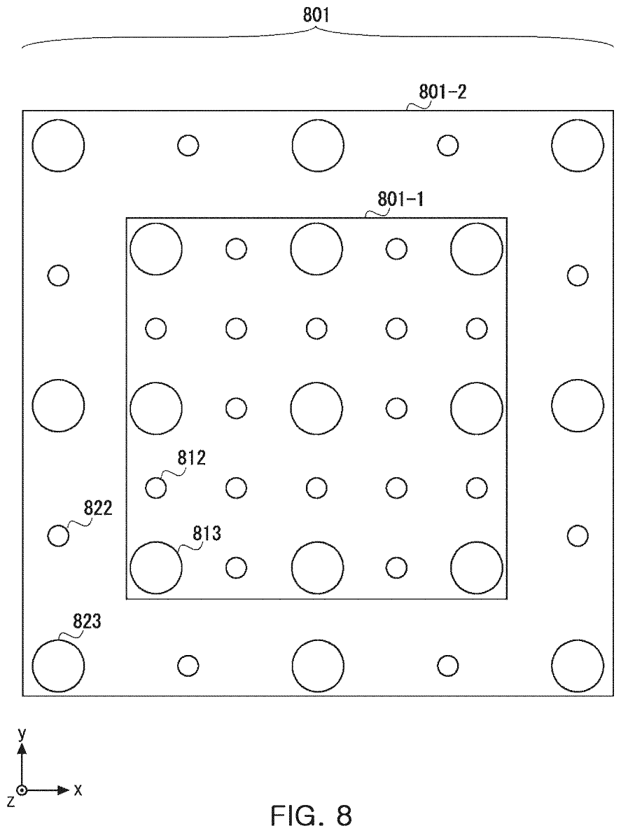

In some example embodiments, a semiconductor manufacturing apparatus, capable of handling chips to correspond to a plurality of chip sizes, will be described. FIG. 8 is a view illustrating an example of an adsorption unit of a semiconductor manufacturing apparatus according to some example embodiments.

As illustrated in FIG. 8, an adsorption unit 801 may include a first adsorption region 801-1 and a second adsorption region 801-2. The second adsorption region 801-2 may be disposed outside, e.g. may surround, the first adsorption region 801-1.

The first suction region 801-1 may include a plurality of first pressing holes 812 and a plurality of first suction holes 813. The second suction region 801-2 may include a plurality of second pressing holes 822 and a plurality of second suction holes 823. The first suction hole 813 may be disposed adjacent to an edge of the first suction region 801-1. The second suction hole 823 may be disposed adjacent to an edge of the second suction region 801-2.

When a chip having a chip size corresponding to the first suction region 801-1 is handled, gases may be suctioned from the plurality of suction holes 813 at the same time as (e.g. at least partially simultaneously as or at least partially concurrently as) gases are ejected from the plurality of pressing holes 812.

In addition, when a chip having a larger chip size, such as a chip size corresponding to the second suction region 801-2, gases may be suctioned from the plurality of suction holes 813 and 823 at the same time as gases are ejected from the plurality of pressing holes 812 and 822.

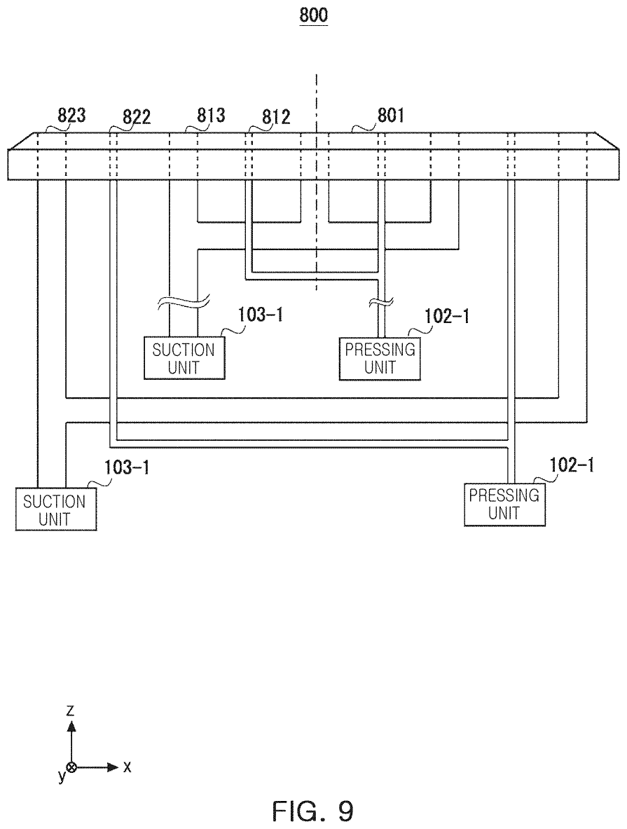

FIG. 9 is a view illustrating a schematic configuration of a semiconductor device according to some example embodiments. In FIG. 9, a semiconductor manufacturing apparatus 800 may include a suction unit 801, a first pressing unit and a second pressing unit 102-1 and 102-2, and a first suction unit and a second suction unit 103-1 and 103-2.

The suction unit 801 may be the suction unit described with reference to FIG. 8. The first and second pressing units 102-1 and 102-2 have the same configuration as the pressing unit 102 of some example embodiments. In addition, the first and second suction units 103-1 and 103-2 have the same configuration as the suction unit 103 of some example embodiments.

When a chip having a chip size corresponding to the first suction region 801-1 is handled, the first pressing unit 102-1 and the first suction section 103-1 may operate, whereas the second pressing unit 102-2 and the second suction unit 103-2 may not operate.

When a chip having a larger size such as a chip size corresponding to the second suction region 801-2 is handled, the first and second pressing units 102-1 and 102-2 and the first and second suction units 103-1 and 103-2 may operate.

The above operations may be controlled by a controller, not illustrated.

As described above, the semiconductor manufacturing apparatus according to some example embodiments may handle chips to correspond to a plurality of chip sizes.

As described in some example embodiments, a plurality of pressing units and a plurality of suction units are provided. However, a plurality of pressing holes 812 and 822 may be connected to a single pressing unit through a valve disposed between the single pressing unit and the plurality of pressing holes 812, and/or a plurality of suction holes 813 and 823 may be connected to a single suction unit through a valve disposed between the single suction unit and the plurality of suction holes 813 and 823. Alternatively or additionally, a pressing hole for ejecting gas and a suction hole for suctioning gas may be selected depending on whether a value is opened or closed.

The present disclosure is not limited to the above-described some example embodiments, and appropriate modifications may be made without departing from the technical scope of the present disclosure. For example, in the above some example embodiments, gas may be not only air but also a single component gas such as nitrogen and/or a mixed gas. For example, the gas may be, in detail, an inert gas such as helium.

Alternatively or additionally, a cross-sectional shape of each of the suction hole and/or of the pressing hole is not limited to a circular shape illustrated in the above some example embodiments, but may be an elliptical shape, a polygonal shape, and/or the like.

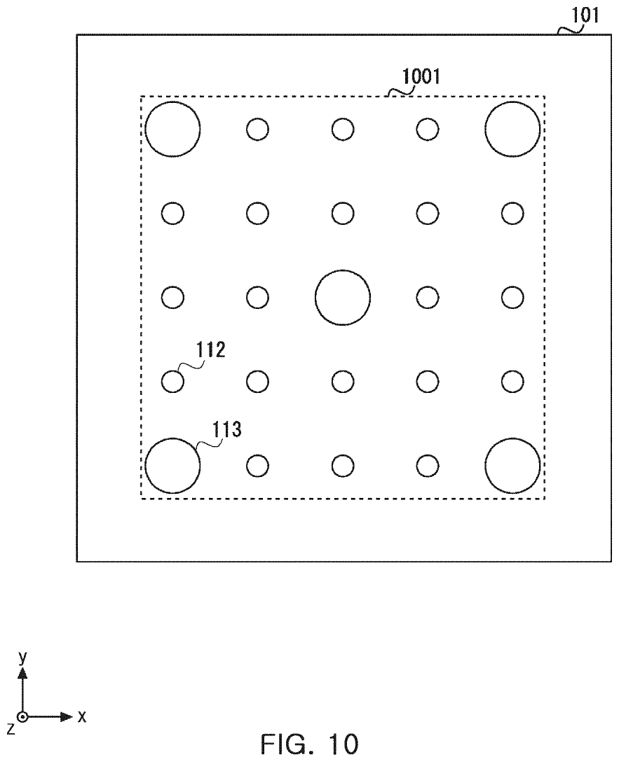

Alternatively or additionally, the pressing hole 112 and the suction hole 113 may be disposed in positions corresponding to a chip to be handled, and thus, may be placed in a location within a size of the suction unit 101. FIG. 10 is a view illustrating an example of an adsorption embodiment of a semiconductor manufacturing apparatus according to other some example embodiments. As illustrated in FIG. 10, an adsorption unit 101 may have a larger size than a chip 1001 to be handled. A pressing hole 112 and a suction hole 113 may be disposed in locations corresponding to the chip 1001 to be handled.

As described above, a semiconductor manufacturing apparatus and/or a chip handling method according to example may satisfy either or both maintenance of a location of a chip in a horizontal direction and high degree of cleanliness.

While some example embodiments have been shown and described above, it will be apparent to those of ordinary skill in the art that modifications and variations could be made without departing from the scope of some example embodiments as defined by the appended claims.

What is claimed is:

1. A semiconductor manufacturing apparatus comprising:
an adsorption unit defining a plurality of pressing holes in the adsorption unit, the plurality of pressing holes configured to eject gas, and defining a plurality of suction holes in the adsorption unit, the plurality of suction holes configured to suction the gas and to handle a semiconductor chip through the gas,
wherein at least one of the suction holes is adjacent to at least one of an apex of the adsorption unit or an edge of the adsorption unit.

2. The semiconductor manufacturing apparatus of claim 1, further comprising:
a pressing unit connected to the pressing holes, the pressing unit configured to deliver the gas; and
a suction unit connected to the suction holes, the suction unit configured to suction the gas.

3. The semiconductor manufacturing apparatus of claim 1, wherein a sum of cross-sectional areas of the plurality of suction holes is greater than a sum of cross-sectional areas of the plurality of pressing holes.

4. The semiconductor manufacturing apparatus of claim 1, wherein the adsorption unit includes a first adsorption region and a second adsorption region surrounding the first adsorption region, and
the plurality of suction holes include a first suction hole in the first adsorption region and adjacent to an edge of the first adsorption region, and a second suction hole in the second adsorption region and adjacent to an edge of the second adsorption region.

5. The semiconductor manufacturing apparatus of claim 1, wherein the adsorption unit has a shape of a polygon when viewed in plan view.

6. The semiconductor manufacturing apparatus of claim 5, wherein the adsorption unit has a shape of a triangle when viewed in plan view.

7. The semiconductor manufacturing apparatus of claim 5, wherein the adsorption unit has a shape of a pentagon when viewed in plan view.

8. The semiconductor manufacturing apparatus of claim 1, wherein at least one of the suction holes is adjacent to an apex of the adsorption unit, and at least one other of the suction holes is adjacent to a an edge of the adsorption unit.

9. The semiconductor manufacturing apparatus of claim 1, wherein at least one of the suction holes in a center of the adsorption unit.

10. The semiconductor manufacturing apparatus of claim 1, wherein the adsorption unit corresponds to a table.

11. The semiconductor manufacturing apparatus of claim 1, further comprising:
a pressing unit tube connecting the pressing unit to at least one of the pressing holes.

12. The semiconductor manufacturing apparatus of claim 1, further comprising:
a suction unit tube connecting the suction unit to at least one of the suction holes.

13. The semiconductor manufacturing apparatus of claim 1, wherein the apex of the adsorption unit corresponds to a sharp corner of the adsorption unit.

14. The semiconductor manufacturing apparatus of claim 1, wherein the apex of the adsorption unit corresponds to a beveled corner of the adsorption unit.

15. The semiconductor manufacturing apparatus of claim 1, wherein the apex of the adsorption unit corresponds to a chamfered corner of the adsorption unit.

16. The semiconductor manufacturing apparatus of claim 1, wherein at least one of the pressing holes has a size of 50 μm or less.

17. The semiconductor manufacturing apparatus of claim 1, wherein at least one of the suction holes has a size of between 0.4 mm and 0.6 mm.

18. A semiconductor manufacturing apparatus comprising:
an adsorption table defining a plurality of pressing holes within the adsorption table, the plurality of pressing holes configured to eject gas, and defining a plurality of suction holes in the adsorption table, the plurality of suction holes configured to suction the gas and to handle a semiconductor chip through the gas,
wherein at least one of the suction holes is adjacent to at least one of a corner of the adsorption table or an edge of the adsorption table.

19. The semiconductor manufacturing apparatus of claim 18, wherein at least one of
(A) the plurality of suction holes are symmetrically arranged in the adsorption table, or
(B) the plurality of pressing holes are symmetrically arranged in the adsorption table.

20. A chip handling method comprising:
using an adsorption unit surrounding a plurality of pressing holes configured to eject gas and a plurality of suction holes configured to suction the gas and to handle a semiconductor chip through the gas, the adsorption unit configured to suction the gas from the suction holes at the same time as the gas is ejected from the pressing holes,
wherein at least one of the suction holes is in a location adjacent to at least one of an apex of the adsorption unit or an edge of the adsorption unit.
